(19) United States
(12) Patent Application Publication
(10) Pub. No.: US 2009/0258214 A1
(43) Pub. Date: Oct. 15, 2009

(54) VAPOR-DEPOSITED COATING AND THERMALLY STRESSABLE COMPONENT HAVING SUCH A COATING, AND ALSO A PROCESS AND APPARATUS FOR PRODUCING SUCH A COATING

(76) Inventors: Erwin Bayer, Dachau (DE); Jurgen Steinwandel, Uhldingen-Muhlhofen (DE); Stefan Laure, Stuttgart (DE)

Correspondence Address: MCANDREWS HELD & MALLOY, LTD, 500 WEST MADISON STREET, SUITE 3400, CHICAGO, IL, 60661, US

(21) Appl. No.: 12/422,555

(22) Filed: Apr. 13, 2009

Related U.S. Application Data
(63) Continuation of application No. PCT/DE2007/001859, filed on Oct. 17, 2007.

(30) Foreign Application Priority Data
Oct. 27, 2006 (DE) 102006050789.4

(51) Int. Cl. B32B 3/26; C08J 9/16; C23C 16/30; C23C 16/00; B05D 5/00

(52) U.S. Cl. 428/304.4; 521/56; 427/255.6; 118/715; 427/243; 427/569

(57) ABSTRACT

The present technology relates to a vapor deposited coating for a thermally stressable component, which comprises deliberately introduced pore formers. This distinguishes the coating from the conventional vapor deposited coatings, which, owing to the coating method do not exhibit pores. Moreover, it distinguishes it from sprayed-on coatings, which do not exhibit any pores or only irregularly shaped pores that are formed arbitrarily. In addition, the present technology relates to a method and a device for producing such a coating.

### RELATED APPLICATIONS

This application is a continuation of International Application Serial No. PCT/DE2007/001859 (International Publication Number WO 2008/049392 A2), having an International filing date of Oct. 17, 2007 entitled “Aufgedamfte Beschichtung Und Thermisch Belastbares Bauteil Mit Einer Solchen Beschichtung, Sowie Vergahren Und Vorrichtung Zur Herstellung Einer Solchen Beschichtung” (“Vapor-Deposited Coating and Thermally Stressable Component Having Such a Coating, and also a Process and Apparatus for Producing Such a Coating”). International Application No. PCT/DE2007/001859 claimed priority benefits, in turn, from German Patent Application No. DE 10 2006 050 789.4, filed Oct. 27, 2006. International Application No. PCT/DE2007/001859 and German Application No. DE 10 2006 050 789.4 are hereby incorporated by reference herein in their entireties.

### FEDERALLY SPONSORED RESEARCH OR DEVELOPMENT

[Not Applicable]

### MICROFICHE/COPYRIGHT REFERENCE

[Not Applicable]

### BACKGROUND OF THE INVENTION

The present technology relates to a vapor deposited coating and a thermally stressable component with such a coating as well as a method and a device for producing such a coating. Examples of related coatings, components, methods and devices are disclosed, for example, in the German Patent Application No. DE 10 2004 033 054 A1, which is hereby incorporated by reference in its entirety.

In the process for coating workpieces, gaseous, liquid and/or solid materials are deposited on the workpieces.

Known methods for depositing gaseous materials include, for example, so-called chemical vapor deposition or physical vapor deposition (CVD/PVD). In these methods, the first step is to evaporate the coating material, which is usually present in the solid state, and then to solidify it again on the surface that is to be coated. Such a condensation takes place in the atomic order of magnitude subject to chemical and/or physical interactions. The coating that forms is characterized by a high homogeneity and high gap contouring. That means that even filigree structures or capillaries can be uniformly coated without having to substantially smooth out the structures or to seal the capillaries. However, such coatings exhibit a columnar structure, the thermal resistance of which is the lowest orthogonally to the coating direction.

Known methods for depositing liquid materials include, for example, a plurality of thermal spray methods. Particularly efficient methods are the wire flame spray process (FDS) and the wire arc light spray process (LDS). In this case wire or flux cored welding wire adjuvants are melted in an electric arc light and centrifuged in the form of droplets on the surface of the workpiece using an atomizing gas. The droplets unite superficially on the substrate to form a more or less porous layer. In so doing, the result is generally a conventional drop-shaped or plate-shape joint morphology with predominantly mechanical interlocking, which leads to non-homogeneous layer properties and a comparably low tensile bond strength. In addition, the thermal spray methods exhibit only very slight gap contouring. That means that filigree structures or capillaries are difficult to coat uniformly, but rather the filigree structures are in essence smoothed out or the capillaries are sealed.

### BRIEF SUMMARY OF THE INVENTION

The object of the present technology is to provide a vapor deposited coating and a thermally stressable component with such a coating as well as a method and device for producing such a coating, which exhibits high homogeneity and gap contouring as well as good thermal resistance.

The present technology relates to a vapor deposited coating for a thermally stressable component, which comprises deliberately introduced pore formers. This distinguishes the coating from the conventional vapor deposited coatings, which, owing to the coating method do not exhibit pores. Moreover, it distinguishes it from sprayed-on coatings, which do not exhibit any pores or only irregularly shaped pores that are formed arbitrarily. In addition, the present technology relates to a method and a device for producing such a coating.

The present technology provides a vapor deposited coating comprising pore forming agents. In certain embodiments the coating is for thermally stressable components, in particular, for a gas turbine of an aircraft. In certain embodiments, the pore forming agents can be fullerenes, nano-balls, micro-balls and/or readily volatilizable materials, such as polystyrene beads In certain embodiments of the present technology, the vapor deposited coating exhibits a gradient of the composition of the vapor deposited material and/or a gradient of the concentration, type and/or size of the pore forming agents. In certain embodiments, the vapor deposited coating comprises reinforcing materials, which may be fibrous and/or ceramic. In certain embodiments, the vapor deposited coating can be configured as an adhesion promoting layer and/or a thermal insulation layer.

Certain embodiments of the present technology provide thermally stressable components comprising the aforementioned coating. Certain embodiments provide systems and methods for providing the vapor deposited coating, for example, by means of PVD and/or CVD, by incorporating pore forming agents into the coating during the vapor deposition process. Additionally, certain embodiments provide a device for producing a vapor deposited coating by means of PVD and/or CVD, the device comprising process equipment for incorporating pore forming agents into the coating.

### BRIEF DESCRIPTION OF SEVERAL VIEWS OF THE DRAWINGS

FIG. 1 depicts a detail of a component surface comprising a base material with a vapor deposited coating, a thin layer of a vapor deposited base material, an adhesion promoting layer, an intermediate layer, a thermal insulation layer and a cover layer in accordance with certain embodiments of the present technology.

### DETAILED DESCRIPTION OF THE INVENTION

The present technology provides the desired vapor deposited coating, in particular for thermally stressable components, (such as, for example, for a gas turbine of an aircraft engine), by providing a coating comprising pore forming agents, which are incorporated in a purposeful manner. In this case the pore forming agents may be configured, for example, as fullerenes and/or nano-balls and/or micro-balls (for example, metallic hollow beads) and/or readily volatilizable materials, for example, polystyrene beads. The pore size can be adjusted, as a function of the type of pore forming agents that are used, from the nanometer range up into the micrometer range. Preferably the pore forming agents exhibit a defined, particularly uniform shape; they are, for example, all spherical.

Such a coating, according to the present technology, exhibits, on the one hand, a high homogeneity and gap contouring owing to the manner in which the coating is deposited—by evaporation—and, on the other hand, a high thermal resistance, as compared to a purely vapor deposited coating, owing to the pore forming agents that the coating comprises. This makes the coating of the present technology particularly suited for thermally stressable components, such as for a gas turbine of an aircraft engine, in particular because the narrow cooling air boreholes that are necessary in such gas turbines can be coated with the coating of the present technology so that these cooling air boreholes are adequately heat insulated without plugging them during the coating process or even their becoming just intolerably constricted.

The coating of the present technology has proven to be particularly advantageous if it exhibits a gradient of the composition of the vapor deposited material and/or if it exhibits a gradient of the concentration and/or the type, particularly the size, of the comprised pore forming agents.

Such gradients make it possible to continuously vary the required material properties and to provide simultaneously smooth material transitions, which exhibit good tensile bond strength in all layer areas.

Similarly it is advantageous for the vapor deposited coating to comprise reinforcing materials, in particular, fibrous, preferably ceramic ones. These reinforcing materials are disposed preferably in the area of the pore forming agents and enhance there the bonding strength in such areas.

The fibrous reinforcing materials may be incorporated into the coating as short fibers in a manner analogous to that of the pore forming agents or also together with the pore forming agents. As an alternative, long fibers may also be disposed as a woven fabric or a bonded fabric or the like on the surface to be coated and then enveloped by the coating. Particularly suited are ceramic fibers owing to their excellent reinforcing properties and simultaneously negligible weight.

Round pores promote crack formation less than irregularly shaped pores as is the case in the thermal spraying process. The use of reinforcing materials further reduces the probability of crack formation.

The inventive coating has proven to be particularly advantageous if it is configured as an adhesion promoting layer and/or as a thermal insulation layer.

The adhesion promoting layer may be constructed, for example, of MCrAlY material. In this case M is selected from the elements iron, nickel, cobalt or mixtures thereof, or from PtAl. The pore forming agents that comprise these materials compensate for the differences in the thermal expansion between the surface that is to be coated and a thermal insulation layer. In addition, the pore forming agents enhance the thermal resistance of the adhesion promoting layer.

As an alternative or in addition, the inventive coating may comprise a thermal insulation layer. Suitable materials for such layer include those based on Mx₂O₃ and/or MyO, where Mx is selected from the lanthanoids, in particular lanthanum, cerium, neodymium, or mixtures thereof, and where My is selected from the alkaline earth metals, the transition metals and the rare earths or mixtures thereof, preferably from magnesium, zinc, cobalt, manganese, iron, nickel, chromium, europium, samarium or mixtures thereof. Similarly zirconium oxide, in particular yttrium stabilized zirconium oxide, or lanthanum zirconate or other oxides or suicides, are suitable. The naturally-present thermal resistance of such material layers is raised significantly higher by the comprised pore forming agents.

The coating of the present technology can be particularly advantageous, if it is vapor deposited on a thermally stressable component, in particular on a component of a gas turbine of an aircraft engine, and if it exhibits an adhesion promoting layer, which is deposited on a component surface, and a thermal insulation layer, which is deposited on the adhesion promoting layer.

A metallic component of a gas turbine that is provided with cooling air boreholes and the coating of the present technology achieves the requisite thermal insulation without plugging the cooling air boreholes or having to do time-consuming re-finishing work and simultaneously guarantees a high wear resistance.

Suitable base materials for such thermally stressable components are iron, nickel or cobalt alloys.

The present technology solves the problem associated with the method for producing a vapor deposited coating by means of PVD or CVD in that during the vapor deposition additional pore forming agents are incorporated into the coating that forms. In this case, for example, fullerenes and/or nano-balls and/or micro-balls (for example, metallic hollow beads) and/or readily volatilizable materials, for example, polystyrene beads, may be used as the pore forming agents.

The specific thermal conductivity and/or thermal resistance can be influenced over a wide range by the choice of the type, size and concentration and/or number of pore forming agents.

In principle, it is advantageous, where possible, to expose the pore forming agents to a coating vapor, which, if possible, is cooled for just a short period of time. However, the decisive factor is the energy transfer from the vapor to the pore forming agents. That is, at lower vapor density higher temperatures are permissible. At atmospheric pressure the stressability limit of most pore forming agents is approximately 300° C.; however, for some it is significantly below that figure, and for a few it can be higher. As a consequence, the pore forming agents should not come into contact with the vaporous coating material, if possible, until it is on the surface to be coated or just prior to being applied to the surface, because the thermal energy of the coating material can be dissipated then via the surface relatively quickly into the deeper layers of the component without damaging or even destroying the pore forming agents.

Brief contact between the pore forming agents and the hot gas phase can be assured in a particularly easy way if an oriented plasma jet is used for the vapor deposition of the coating material. The method and device for generating a suitable plasma jet are described, for example, in the aforementioned German Patent Application No. DE 10 2004 033 054 A1. If at this point the pore forming agents are also deposited by means of a carrier gas stream, then both jets can be oriented advantageously in such a manner that they do not meet until on or just prior to being applied to the surface to be coated. Thus, the amount of time the hot vapor phase acts on the comparatively sensitive pore forming agents is very short, and as a result, the energy transfer is correspondingly low.

In this embodiment, the carrier gas stream may be inert, in order to influence as little as possible the vapor jet. Alternatively, the carrier gas stream may also consist of a reactive gas, which reacts with the vapor jet and in this way brings about a CVD.

It is also advantageous if the composition of the vapor deposited material is changed during the vapor deposition. In this way it is possible to provide continuous transitions—for example, beginning from a base material that is to be coated with a smooth transition to an adhesion promoting layer, which in turn passes over smoothly into a thermal insulation layer, which in turn passes over smoothly into an erosion resistant cover layer.

As an alternative or in addition to, it can be advantageous if the type, size and/or concentration of the comprised pore forming agents is changed during the vapor deposition. In this way it is possible to influence the specific thermal conductivity and/or the thermal resistance of the coating over wide ranges.

As an alternative or in addition to, it can be additionally advantageous to incorporate reinforcing materials, in particular fibrous, preferably ceramic ones. These reinforcing materials enhance the bonding strength and are incorporated, therefore, preferably in the area of the pore forming agents.

The fibrous reinforcing materials can be incorporated into the coating as short fibers in a manner analogous to that of the pore forming agents or also together with said pore forming agents. As an alternative, long fibers can also be disposed as a woven fabric or a bonded fabric or the like on the surface to be coated and then enveloped by the condensing vapor phase.

The method of the present technology can be applied particularly advantageously if the coating is configured as an adhesion promoting layer through the suitable choice of the respective material composition adjacent to the component surface, and then, building up on said adhesion promoting layer, configured as a thermal insulation layer. Such a construction exploits the inventive advantages of high homogeneity and gap contouring as well as good thermal resistance.

The present technology solves the problem with respect to the device for producing a vapor deposited coating by means of PVD or CVD in that the device exhibits process equipment for introducing the pore forming agents into the coating that forms.

Such a device is configured in a particulary advantageous manner if it exhibits process equipment for generating an oriented plasma jet of the material to be deposited by evaporation, and if the process equipment for introducing the pore forming agents exhibits process equipment for generating an oriented carrier gas jet.

A plasma jet, according to the present technology, is (as compared to a thermal spray jet) in essence free of drop-shaped spray material having drop sizes exceeding 500 nm. It is particularly preferred that the maximum size of the drops in the plasma jet are below 200 nm when emerging from the nozzle. Particularly under low pressure conditions the plasma jet can also be described as an atomic fog, which is formed by atoms and atomic micro clusters, thus aggregates of a few atoms up to some thousands of atoms.

The oriented plasma jet allows the targeted coating of selected surface areas with the vapor formed in said plasma jet. The oriented carrier gas jet allows the targeted introduction of pore forming agents in selected surface areas. In this case the carrier gas stream may be inert, in order to influence as little as possible the vapor jet, or the carrier gas stream may also consist of a reactive gas, which reacts with the vapor jet and in this way brings about a CVD.

Preferably the process equipment for producing the oriented carrier gas jet is designed in such a manner that it makes possible an orientation of the carrier gas jet. In this way the carrier gas jet can be oriented—as a function of the type, size and concentration of the pore forming agents—with respect to their thermal stressability optimally in relation to the plasma vapor jet. That is, the energy transfer from the vaporous coating material to the pore forming agents can be optimized. It is usually advantageous for both jets to meet just before the surface or even first on the surface.

It is also advantageous if the inventive device exhibits at least one unit for metering at least one type of pore forming agents, in order to be able to vary their concentration upon introduction into the coating to be created. In the event of several kinds and grades, in particular size grades, a mixing device may also be advantageous, in order to allow a uniform blending of the different types and/or grades.

The vapor deposited coating of the present technology and a thermally stressable component with such a coating as well as the inventive method and the inventive device for producing such a coating are explained in detail below with reference to the Figure and one embodiment.

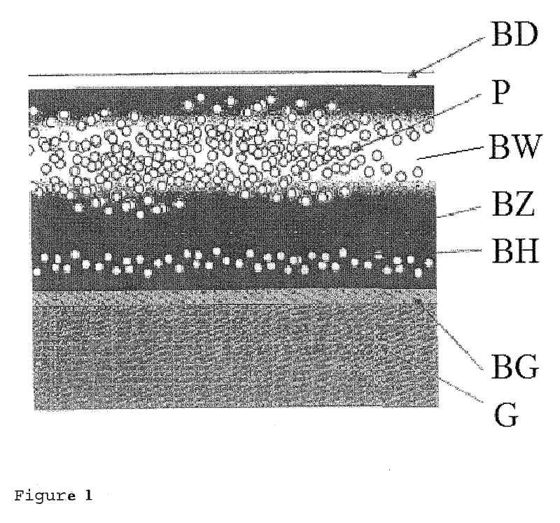

FIG. 1 depicts a detail of a component surface composed of a base material G with a vapor deposited coating B. The vapor deposited coating B comprises a thin layer BG made of a vapor deposited base material, over which is an adhesion promoting layer BH, over which is an intermediate layer BZ, over which is a thermal insulation layer BW and finally a cover layer BD.

According to one embodiment, coating B is vapor deposited on the surface, which belongs to a component of a gas turbine and is to be exposed to high thermal stress, in one single working step. The cooling air boreholes, which are necessary in the component, are not sealed by the coating, which is deposited by evaporation in accordance with the present technology.

Then the component surface, made of the base material G (for example, a highly stressable iron alloy) is cleaned of oxide layers and other impurities. This can be done by a transferred arc light, by glow discharge or by plasma ablation. The latter may ensue in an especially easy way in the inventive device, which is intended for producing the coating and will be explained in detail below.

After the cleaning process, the next step is to vapor deposit a very thin layer BG (a few atomic layers) made of a base material G. On this layer an adhesion promoting layer BH is vapor deposited. In this embodiment, the composition of the vapor jet is changed continuously from the composition of the base material G up to the composition of the adhesion promoting material PtAl, so that the result is a smooth transition of the layers. During the coating process with just the adhesion promoting material, the pore forming agents P are deposited on the surface in the form of metallic nano-balls and micro-balls by means of an inert carrier gas jet and enclosed here by the adhesion promoting material. A dense intermediate layer BZ made of Al₂O₃ is vapor deposited on the adhesion promoting layer BH. Even between the layers BH and BZ there is a smooth transition of the material composition. A thermal insulation layer BW made of lanthanum hexaaluminate is vapor deposited on the intermediate layer BZ. The thermal insulation layer is constructed in the manner of a column or as layers as a function of the temperature control. Even between the layers BZ and BW there is a smooth transition of the material composition. During the coating process with just the thermal insulation material the pore forming agents P are deposited on the surface in the form of metallic nano-balls and micro-balls by means of an inert carrier gas jet and enclosed there by the thermal insulation material. A ceramic cover layer BD made of zirconium oxide is vapor deposited on the thermal insulation layer BW. Even between the layers BW and BD there is a smooth transition of the material composition.

The pore forming agents P in the adhesion promoting layer BH help balance the varying thermal expansion coefficients between the base material G and the thermal insulation layer BW. The pore forming agents P in the thermal insulation layer BW serve primarily to reinforce the thermal resistance of this layer. The cover layer BD guarantees good protection against erosion.

A device for producing such a coating corresponds with the device disclosed in the German Patent Application No. DE 10 2004 033 054 A1 and exhibits additional process equipment for introducing pore forming agents P into the coating B. The process equipment for introducing the pore forming agents P comprises alignable process equipment for producing an oriented carrier gas jet.

Therefore, the device of the present technology comprises the following significant components:
a feed mechanism for wire-shaped coating material (as an alternative the feed of liquid or powdery coating material is also possible);
a gas supply for the carrier gas for the evaporated coating material;
a plasma chamber with anode and cathode in wire form for producing a high current plasma arc
and an outlet nozzle for an oriented plasma jet;
   where the cathode for generating the high current plasma arc is formed by wire-shaped, electrically conductive coating material and further comprising:
a supply device for the pore forming agents P;
a gas supply for the carrier gas for the pore forming agents P;
and an alignable outlet nozzle for an oriented carrier gas stream, laden with pore forming agents P.

In this embodiment, the decisive factor is that the plasma gap in the burner is very long, so that the material can be fed directly into the central plasma jet.

The wire-shaped coating material is conveyed by feeding the wire through a slotted nozzle into the plasma chamber. The carrier gas is introduced on the wire feed side by means of the device for the gas supply. In order to supply more gases, in particular reactive gases, there is an additional gas introduction, which in this case is arranged near the arc light discharge zone. Similarly, however, it is also possible to introduce the additional gas after premixing by way of the gas supply device.

The pore forming agents are directed by gravity or the carrier gas to the area to be coated and embedded there by a vapor cloud.

The vapor deposited coating of the present technology and the components, which can be thermally stressed with said coating, as well as the method and the device for producing such a coating are characterized by their good thermal resistance with simultaneously very homogeneous deposition and excellent gap contouring or contour accuracy.

Preferred applications of the present technology are in the production of thermal insulation layers and/or fireproof layers on metallic substrates, preferably on low pressure coatings, in particular for a gas turbine of an aircraft engine. However, the method and device can also be used at normal or even excessive pressure.

The present technology has now been described in such full, clear, concise and exact terms as to enable a person familiar in the art to which it pertains, to practice the same. It is to be understood that the foregoing describes preferred embodiments and examples of the present technology and that modifications may be made therein without departing from the spirit or scope of the present technology as set forth in the claims. Moreover, while particular elements, embodiments and applications of the present technology have been shown and described, it will be understood, of course, that the present technology is not limited thereto since modifications can be made by those familiar in the art without departing from the scope of the present disclosure, particularly in light of the foregoing teachings and appended claims. Moreover, it is also understood that the embodiments shown in the drawings, if any, and as described above are merely for illustrative purposes and not intended to limit the scope of the present technology, which is defined by the following claims as interpreted according to the principles of patent law, including the Doctrine of Equivalents. Further, all references cited herein are incorporated in their entirety.

1. A vapor deposited coating comprising pore forming agents.

2. The coating of claim 1, wherein said coating is for thermally stressable components.

3. The coating of claim 2, wherein said coating is for a gas turbine of an aircraft.

4. The coating of claim 1, wherein said pore forming agents belong to the group consisting of fullerenes, nano-balls, micro-balls and readily volatilizable materials.

5. The coating of claim 4, wherein the volatilizable materials are polystyrene beads.

6. The vapor deposited coating of claim 1, wherein the coating exhibits a gradient of the composition of the vapor deposited material.

7. The vapor deposited coating of claim 1, wherein the coating exhibits a gradient of at least one of the concentration, type and size of the pore forming agents.

8. The vapor deposited coating of claim 1, wherein the coating comprises reinforcing materials.

9. The vapor deposited coating of claim 8, wherein the reinforcing materials are at least one of fibrous materials and ceramic materials.

10. The vapor deposited coating of claim 1, wherein the coating is configured as at least one of an adhesion promoting layer and a thermal insulation layer.

11. A thermally stressable component comprising a coating deposited on a surface of the component, said coating comprising pore forming agents and said surface comprising a base material, said base material comprising:
at least one adhesion promoting layer; and
a thermal insulation layer deposited on said at least one adhesion promoting layer.

12. The thermally stressable component of claim 11, wherein said component is used as a component of a gas turbine of an aircraft engine.

13. The thermally stressable component of claim 11, wherein said pore forming agents belong to the group consisting of fullerenes, nano-balls, micro-balls and readily volatilizable materials.

14. The thermally stressable component of claim 11, wherein the coating exhibits a gradient of the composition of the vapor deposited material.

15. The thermally stressable component of claim 11, wherein the coating exhibits a gradient of at least one of the concentration, type and size of the pore forming agents.

16. The thermally stressable component of claim 11, wherein the coating comprises reinforcing materials, said reinforcing materials being selected from the group consisting of fibrous materials and ceramic materials.

17. The thermally stressable component of claim 11, wherein the coating is configured as at least one of an adhesion promoting layer and a thermal insulation layer.

18. A method for producing a vapor deposited coating by vapor deposition, said method comprising the steps:
performing at least one of physical vapor deposition or chemical vapor deposition; and
incorporating pore forming agents into the coating during vapor deposition.

19. The method of claim 18, wherein the pore forming agents incorporated into the coating are selected from the group consisting of fullerenes, nano-balls, micro-balls and readily volatilizable materials.

20. The method of claim 18, further comprising the step of providing an oriented plasma jet, wherein said oriented plasma jet is used for vapor deposition.

21. The method of claim 18, wherein said vapor deposition step further comprises the step of changing at least one of the composition of the vapor deposited material, the type of the pore forming agents and the concentration of the pore forming agents.

22. The method of claim 18, further comprising the step of incorporating reinforcing materials, wherein said reinforcing materials are at least one of fibrous materials and ceramic materials.

23. The method of claim 18, further comprising the steps of:
configuring the coating as an adhesion promoting layer adjacent to a surface of the component, said surface comprising a base material; and
applying said coating to said adhesion promoting layer and forming a thermal insulation layer.

24. A device for producing a vapor deposited coating by physical vapor deposition or chemical vapor deposition, the device comprising process equipment for incorporating pore forming agents into the coating.

25. The device for producing a vapor deposited coating of claim 24, further comprising process equipment for generating an oriented plasma jet of the material to be vapor deposited, and wherein the process equipment for incorporating the pore forming agents further comprises process equipment for generating an oriented carrier gas jet.

26. The device for producing a vapor deposited coating of claim 24, wherein the carrier gas jet is orientable.
